(19) United States
(12) Patent Application Publication
(10) Pub. No.: US 2005/0020087 A1
(43) Pub. Date: Jan. 27, 2005

(54) Method and apparatus for removing an edge region of a layer applied to a substrate and for coating a substrate and a substrate

(76) Inventors: Hermann Wagner, Meiningen (DE); Bernd Beier, Benshausen (DE); Mario Schiffler, Oepfershausen (DE); Guenter Hess, Meiningen (DE); Peter Rudakoff, Jena (DE); Bernd Hoetzel, Woerrstadt (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/829,392

(22) Filed: Apr. 22, 2004

(30) Foreign Application Priority Data
Apr. 24, 2003 (DE) 103 18 681.6

(51) Int. Cl. H01S 3/08; H01L 21/311

(52) U.S. Cl. 438/700

(57) ABSTRACT

The invention relates to a method and an apparatus for removing an edge region of a layer applied to a substrate and for coating a substrate, in particular, with a photoresist layer. Furthermore, the present invention relates to a substrate, onto which a layer, in particular, a photoresist layer for use in a microlithographic process, is applied, wherein an edge region of the layer is removed according to the invention. In the method, a laser beam is imaged onto the edge region, and the edge region is removed by the laser beam. In this manner, the edge region can be removed reliably and precisely, without damage to or contamination of regions of the layer which are not to be removed.

Method and apparatus for removing an edge region of a layer applied to a substrate and for coating a substrate and a substrate The present application claims convention priority of German patent application No. 103 18 681.6 the whole contents of which is hereby explicitly incorporated by reference.

### FIELD OF INVENTION

The present invention relates to a method and an apparatus for removing an edge region of a layer applied to a substrate and for coating a substrate, in particular with a photoresist layer. Furthermore, the present invention relates to a substrate onto which a layer is applied, of which an edge region is removed according to the invention, in particular, a photoresist layer for use in a microlithographic process.

### BACKGROUND OF THE INVENTION

In the coating of substrates, for example, wafers, maskblanks, photo masks or substrates for use in LCD displays, the peripheral regions and the edges of the substrate are also coated. However, a coating is undesirable in these regions, because abrasion, which may contaminate the substrate, can readily occur as a result of contact with handling tools such as vacuum holding devices. In view of the increasing density of integration of micro-electronic structures, these problems are becoming increasingly serious. Accordingly, attempts have been made to remove the coating from the peripheral and/or edge regions of the substrates.

It is known that a thickened edge region or “edge bead” is formed during the coating of semiconductor wafers with a photo resist by spin coating. During spin coating, a photoresist droplet is applied near the rotational axis of a rapidly rotating wafer; this is distributed radially as a result of centrifugal forces. The edge bead is formed in this context. During subsequent processing stages, in which the wafer is held in place by a holding or clamping medium applied to the edge of the wafer, the thickened edge bead induces forces in the photoresist layer, which can lead to errors in the subsequent exposure to light. Accordingly, various methods have been proposed in the prior art for removing the edge bead.

Edge beads also occur in galvanic coating processes. A conductive metallic coating is often applied by vapour deposition, for example, physical vapour deposition (PVD) as a starting and/or seed layer, onto which a metallic layer is then applied galvanically. The rate of deposition is often greater at the edge of a substrate, which can lead, for example, to different current densities across the substrate and to mechanical stresses.

### RELATED ART

In order to remove edge beads of this kind in a selective manner, the prior art selectively applies a suitable solvent or etching medium to the edge region. U.S. Pat. No. 5,952,050 discloses a method, wherein a solvent is selectively sprayed onto the edge by means of a nozzle. The photoresist dissolved from the edge region is then removed via a vacuum connection by vacuum. U.S. Pat. No. 5,362,608 discloses a solvent and a method for dissolving the edge regions of a wafer.

U.S. Pat. No. 4,875,989 discloses a device for processing wafers, wherein a chemical is applied selectively in a ring-shape to the edge region which is to be removed.

U.S. Pat. No. 6,267,853 discloses a device, wherein an etching medium is sprayed onto the circumferential edge region of a wafer, in order to dissolve an edge bead of a metallic starting and/or seed layer.

WO 01/82001 A1 discloses a device wherein an edge bead of a photo-resist paint layer is selectively exposed to light in a ring shape and then removed.

DE 195 36 474 C2 discloses a method for cleaning a coated work piece, in particular a photo blank for the manufacture of photo masks, which is to be structured. In order to remove non-permanently-adhesive metallic coatings from the peripheral regions and/or edges of a substrate, the same radiation, which is also used for structuring a photoresist, is applied to the peripheral regions and/or the edges. After the irradiation, the peripheral and/or edge region is etched in a conventional manner together with the regions to be structured. The use of a higher intensity of radiation for the removal of an edge bead caused by the spin coating of photoresist is also disclosed.

However, in this case, the radiation is used for structuring or patterning the peripheral and/or edge region, but not for removing the peripheral and/or edge region by evaporation by means of radiation.

DE 199 00 910 A1 discloses a device and a method for cleaning surfaces by means of laser ablation. To achieve a more even distribution of the laser intensity on the surface to be cleaned, circular movement pathways of the laser beam are disclosed. However, this method relates to an alternative to traditional sand-blasting methods for cleaning external surfaces, not to a use with a substrate for use in a microlithographic process.

EP 627 277 discloses a method for rounding and/or further processing of a photo-conductive roller in an electro-photographic image forming device. For this purpose, a laser beam is imaged tangentially onto the surface of the roller.

Another laser removal method, which does not relate to a use with a substrate for use in a microlithographic process, is disclosed in DE 102 05 351 A1, which corresponds to US 2003/0057192 A1.

However, with this method, there is a danger that the photoresist layer will be contaminated by splashes in places which are required for subsequent processing stages, or the photoresist layer may absorb solvent fumes, which may have an unfavourable influence on functional properties, such as sensitivity, dark-removal, adhesion. Some photoresists cannot be removed without trace using this method because of their relative insolubility. In the prior art, mechanical cleaning methods, such as brushing, which could additionally damage the photoresist layer, are frequently used in addition to solvents and/or etching media.

### SUMMARY OF THE INVENTION

It is an object of the present invention to provide a more reliable and simpler method for removing an edge region of a layer applied to a substrate and for coating a substrate with a layer, wherein the substrate is intended for use in a microlithographic method. It is a further object of the present invention to provide a corresponding device and a substrate, which is coated with a layer, in particular, a photoresist layer for use in a microlithographic process, of which an edge region is reliably removed.

Summary of the Invention

According to the present invention there is provided a method for removing an edge region of a layer applied to a substrate for use in a microlithographic process, in which method, a laser beam is imaged onto the edge region, and the laser beam removes the edge region by evaporation. It is advantageous that a laser beam can be imaged very accurately and simply, so that the edge region to be removed can be specified with a great degree of accuracy, which is essentially only limited by diffraction effects or related effects. It is also advantageous that various parameters of a laser beam, for example, laser power, laser pulse duration, diameter of the laser beam in the region of the focus and/or in the edge region, can be varied in a simple manner, so that a great many degrees of freedom are available, according to the invention, for specifying the quality of the removal of the edge region.

In particular, the choice of wavelength of the laser beam used provides a parameter, which can be optimally adapted in a surprisingly simple manner to the properties of the material to be removed from the edge region. For example, the wavelength can be adjusted to, or close to, the maximum of an absorption band or a rotational band of the material to be removed.

Preferably, the laser beam is appropriately focused on the edge region to be removed using an imaging means, for example, a lens or a lens system, a mirror or a mirror system, or a diffractive optical element, so that the edge region to be removed can be defined more precisely, and the energy density to be applied to this region can be even further increased. The laser beam is expediently focused on the edge region in the form of a point or spot, which achieves a maximum density at the focus. The laser beam can also be imaged in a linear form, so that a linear edge region can be removed at one and the same time. By preference, the linear focus region is orientated perpendicular to the edge of the substrate. A cylindrical lens or a system of cylindrical lenses or elongated hollow mirrors can be used to achieve such linear imaging.

According to a first embodiment, the laser beam is imaged in such a manner onto the edge region, that the laser beam is incident onto the surface of the substrate in an essentially perpendicular direction. In this configuration, the substrate can be moved to and fro at essentially the same height without consideration for interfering optical elements etc. Alternatively, the laser beam may also be imaged onto the edge region in such a manner that the laser beam is incident onto a plane spanned by the surface of the substrate in an essentially parallel direction. With this configuration, the laser beam is incident onto the photoresist on the surface of the substrate in an essentially glancing manner and removes a linear region parallel to the surface of the substrate. In particular, if the substrate is circular, it is preferable for the laser beam to be incident onto the edge of the circular substrate, for example, a wafer or a mask blank, tangentially. In this manner, a concentric edge region can be removed as a whole simply by rotating the substrate. Of course, the laser beam can also be imaged onto the substrate and the edge region in any other appropriate configuration.

Preferably, the parameters of the laser beam, in particular, the laser power, pulse duration and wavelength, may be selected so that the edge region to be removed evaporates completely or almost completely. Because of the immediate thermal expansion from the vapour arising, mechanical effects may also contribute to a further removal of the edge region. The details of the removal can be determined in a surprisingly simple manner according to the invention by varying the relevant laser parameters and by implementing a series of simple experiments.

In order to avoid contamination with splashes or fumes of the regions of the layer which are not to be removed, a vacuum or a blower device for vacuum-cleaning or blow-cleaning the edge region to be removed is preferably arranged in the proximity of the edge region.

Preferably, the laser beam and the substrate are moved relative to one another, while the laser beam scans and removes the edge region. A further parameter, which may have an effect on the quality of the removal in a surprisingly simple manner, is provided by the velocity with which the laser beam and the substrate move relative to one another. The laser beam and the substrate can be moved relative to one another by mechanical means. For example, the substrate can be passed under the laser beam by robot control or the substrate may be placed on a moving platform, which displaces the substrate in an appropriate manner. Alternatively, the position of the laser beam on the substrate can be moved by optical means. For example, one or more mirrors, which are used for imaging on the edge region, can be moved, for example, by means of piezo actuators; or the mirror(s) can scan the laser beam over the region to be removed. Alternatively, the laser beam can be coupled into an optical fibre and guided towards the substrate, where the optical fibre, and optionally associated optical focusing elements and the substrate can be moved relative to one another. Of course, mechanical and optical systems may be combined in any appropriate manner in order to move the laser beam and the substrate relative to one another.

The laser beam is expediently moved slightly to and fro, while the laser beam removes the edge region. In this manner, it is easier to make the laser power introduced for the removal of material more homogeneous, and a larger edge region can be removed without changing the focusing. The movement to and fro is expediently performed periodically and essentially perpendicular to the edge of the substrate, for example, radially, in the case of a circular substrate. Mechanical and/or optical systems, for example, as mentioned above, may be used for the to and fro movement.

According to the invention, the edge region can be removed extremely accurately. Accordingly, the edge region can be removed in steps essentially perpendicular to the surface of the substrate. Even if an additional paint layer, for example, a photoresist layer is applied to a metallic coating, e.g. a chrome coating, the metallic coating disposed beneath it can be reliably contacted after the edge removal according to the invention, for example, for the discharge during the electron beam writing of a photo mask.

The edge region to be removed is preferably optically scanned by the laser beam, in order to adapt or control a parameter of the laser beam, in particular, its power or pulse duration, so that the edge region can be removed essentially completely. The optical scanning can take place during or following the removal of the edge region. In both cases, the parameters, which influence the quality of the removal, can be more appropriately adjusted. In principle, an optical scanning of this kind may, however, also be carried out on a separate test field, which is designed or coated in an essentially identical manner to the edge region to be removed, either in another position on the substrate or away from the substrate. In this case, a test removal is first carried out on the test field, and the removal of the edge region is not implemented until the quality of the removal from the test field has been found satisfactory. A reflected, scattered or transmitted component of a light ray incident onto the edge region and/or the test field, produced and imaged, for example, by an LED or a laser diode, can be used for the optical scanning of the edge region and/or the test field. A microscopic or macroscopic image of the edge region and/or of the test field to be removed can also be used for the optical scanning; this may, for example, be read into the computer and automatically analysed.

Preferably, an aperture means is used, which prevents the laser beam from being imaged onto regions of the substrate other than the edge regions which are to be removed. For example, if the substrate is circular, the aperture means may be a circular disk placed in the light pathway of the laser beam, which shades or blocks regions of the layer which are not be removed. In order to achieve even more advantageous edge properties of the edge region to be removed, diffraction effects of the aperture means may additionally be used with this embodiment.

According to another aspect of the present invention there is provided a method for coating a substrate with a layer, in particular, a photoresist layer for use in a microlithographic process, in which method, a layer is applied to the substrate, and an edge region of the applied layer is removed using a method according to the present invention. Any coating methods desired may be used for applying the layer, for example, spin coating, dip coating, immersion methods or spraying. With the method according to the present invention, the edge region can be removed in a particularly appropriate manner. According to the invention, the substrate can be coated with a particularly homogeneous and stress-free layer. According to the present invention there is also provided a substrate, which is coated with a layer, an edge region of which is to be removed using the method according to the present invention. The substrate is preferably coated with a photoresist layer for use in a microlithographic method. Preferably, the substrate is a semiconductor substrate and/or wafer. By quite particular preference, the substrate is a mask blank for the manufacture of masks for a microlithographic manufacture and exposure method.

According to the present invention there is also provided an apparatus for removing an edge region of a layer applied to a substrate. The apparatus comprises a laser light source for emitting a laser beam, and an imaging means for imaging the laser beam onto the edge region of the substrate. The laser light source is configured to remove the edge region with the laser beam by evaporation, and the apparatus is configured for implementing of the method according to the invention.

### BRIEF DESCRIPTION OF THE DRAWINGS

Preferred exemplary embodiments of the present invention will be described in greater detail below with reference to the attached diagrams. The drawings are as follows:

FIG. 1 shows a cross-section and a plan view of a first embodiment of an apparatus according to the present invention;

FIG. 2 shows a cross-section and a plan view of a second embodiment of an apparatus according to the present invention;

FIG. 3 shows a cross-section and plan view of a third embodiment of the apparatus according to the present invention for removing an edge region of an essentially rectangular substrate;

FIG. 4 shows a schematic perspective view of a fourth embodiment of the apparatus according to the present invention;

FIG. 5a shows the results from a mechanical scan of an edge region of a mask blank, which has been removed according to the present invention; and

FIGS. 5b and 5c show the results from a mechanical scan of an edge region of a mask blank, which has been removed by spraying a solvent onto the edge region.

In the drawings, identical reference numerals refer to identical elements or functional groups, or to elements or functional groups which operate in an essentially equivalent manner. When studying the following description of preferred exemplary embodiments additional features, modifications and objects according to the present invention will become apparent to a person skilled in the art.

### DETAILED DESCRIPTION OF THE PREFERRED EMBODIMENTS

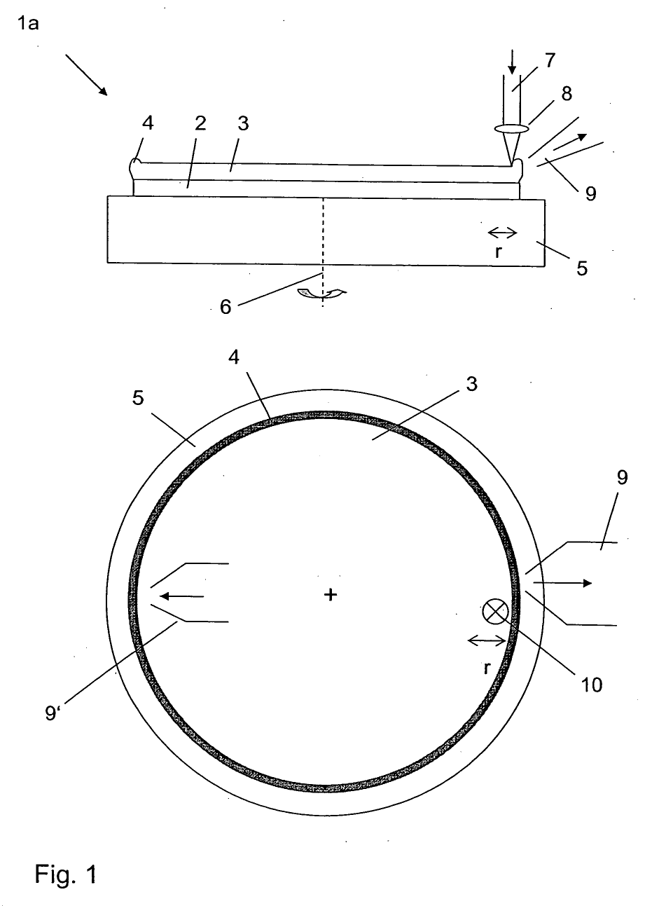

FIG. 1 shows a schematic cross-section and plan view of a first embodiment of an apparatus (hereinafter) 1a according to the present invention. The device 1a comprises a holding means 5, on which a substrate 2 is held. The holding means 5 may, for example, be a vacuum device (vacuum chuck). As indicated by the arrow, the holding means can be rotated about an axis of rotation 6. The holding means 5 may be designed for spin coating a photoresist layer onto the substrate 2, that is to say, for relatively fast rotational velocities. The holding means 5 can also be designed as a holding element in a robot arm or in a production line for semiconductor manufacture.

A layer 3 is applied to the substrate 2. The edge region 4 of the layer 3 is thickened, as shown schematically in FIG. 1. The term “edge region”, as used in this patent application, always refers to regions of the substrate surface and/or the front face of the circumferential edge of the substrate 2 and/or on the rear side of the substrate 2.

The layer 3 may consist of a photoresist, a protective resist, a thin metallic coating or one or more dielectric layers.

A laser beam 7 is imaged by means of a lens 8, which represents one example of an imaging means, onto the edge region 4. At the same time, the laser beam 7 is focused using a lens 8. The focus of the lens 8 lies preferably within the edge region 4, but may also lie slightly above or below the edge region. In the proximity of the focus, the laser beam 7 provides an essentially Gaussian beam contour, of which the length is predetermined essentially by the diameter of the laser beam 7 in front of the lens, by the lens or lens system 8 and the properties of the lenses and/or the lens system 8. The contour of the beam is preferably adjusted in such a manner that the diameter of the focus changes to the minimum extent in the proximity of the layer 3.

In the lower part of FIG. 1, the focus 7 is located radially inwards relative to the shaded edge region 4 which is to be removed. A vacuum device 9 which removes vapour and particles which have been removed from the coating, is arranged in the proximity of the circumferential edge of the substrate 2 and the focus 10 of the laser, so that regions of the layer 3, which are not to be removed and the optical unit of a camera filming the edge region are not contaminated. According to FIG. 1, the vacuum device 9 is arranged above the substrate 2. In principle, the vacuum device 9 may also be arranged in any other appropriate manner, for example, embracing the entire edge region of the substrate 2.

Since the laser beam 7 according to FIG. 1 is incident onto the surface of the substrate in an essentially perpendicular direction, and the vacuum device 9 is arranged above the substrate 2, the substrate 2 can be handled essentially without obstruction at the level of the substrate 2.

In principle, a blower 9′, which blows vapour or particles of the removed coating away from the edge of the substrate may also be provided instead of the vacuum device 9.

In order to remove the edge region 4, the laser beam 7 is moved radially outwards (Arrow r), until the focus 10 is disposed in the edge region 4 to be removed.

Following this, the laser power is appropriately set in order to remove the layer 3 in the region of the laser focus 10 by evaporation. During removal, the substrate 2 continues to be rotated by the holding means 5. Accordingly, the laser beam 7 evenly removes an essentially ring-shaped edge region 4. Additionally, the laser beam 7 may be moved rapidly to and fro in a radial direction in order to remove a wider edge region. In order to achieve a periodic, to-and-fro movement of the laser beam 7, a mirror, which is not illustrated, can be tilted periodically, for example, using a piezo actuator; the lens 8 and/or the lenses of the lens system 8 can be tilted periodically; or an optical fibre guiding the laser beam 7, optionally with an optical imaging unit, can be moved rapidly to and fro.

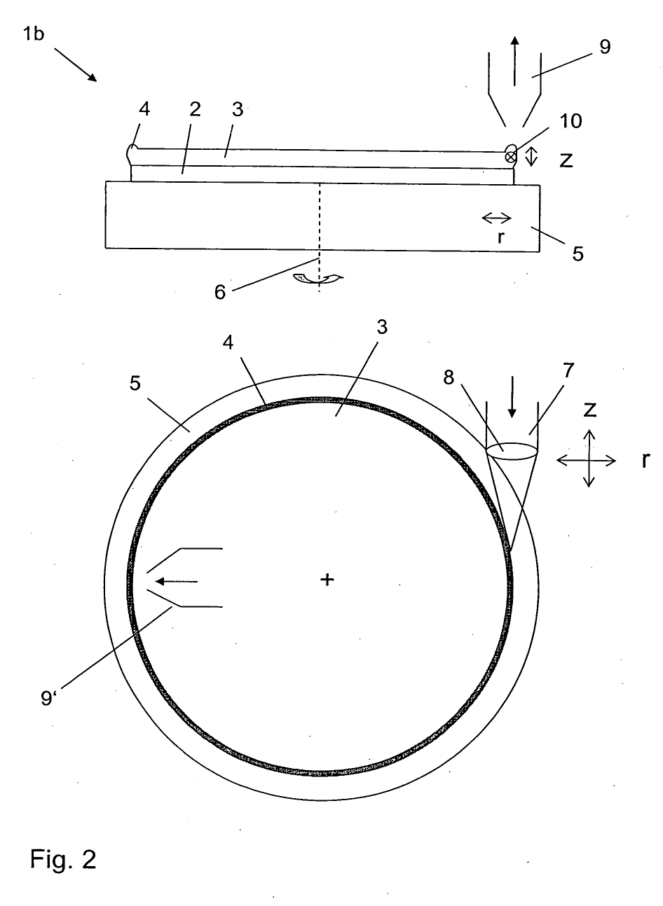

FIG. 2 shows a cross-section and a plan view of a second embodiment of a device 1b according to the present invention. In the second embodiment, the laser beam 7 is imaged onto the edge region 4 in such a manner, that the laser beam 7 is incident onto a plane formed by the surface of the substrate in an essentially parallel direction, and the laser beam is incident onto the edge of the substrate tangentially. During the removal of the edge region 4, the laser beam 7 can be moved rapidly to and fro in a radial direction (arrow r) and/or can be moved rapidly to and fro in the z-direction in order to remove an even larger volume.

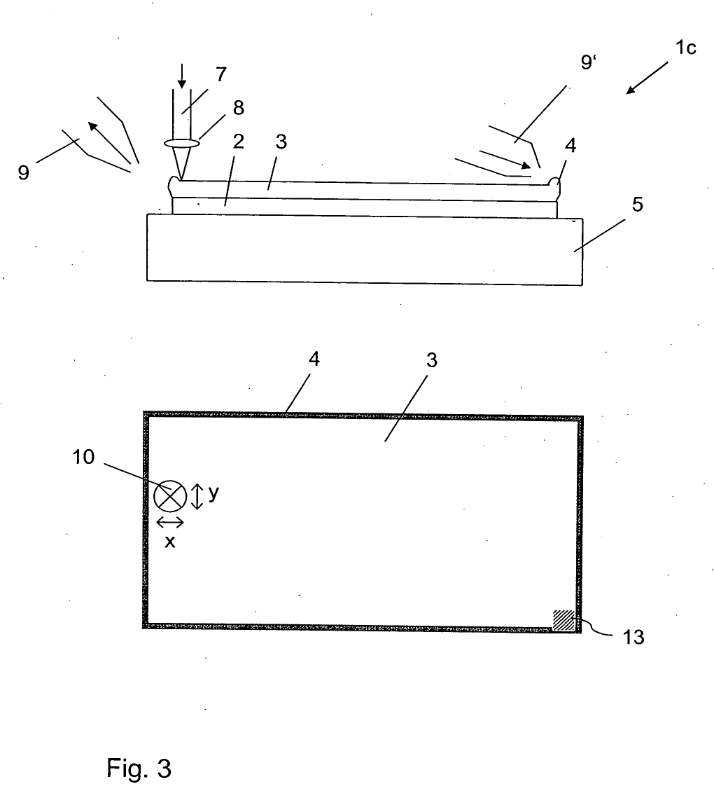

FIG. 3 shows a cross-section and a plan view of a third embodiment of a device 1c according to the present invention. In the third embodiment, an essentially rectangular substrate 2 is processed. According to the third embodiment, the laser beam 7 and the substrate 2 are moved relative to one another in such a manner that the laser beam 7 is moved along the circumferential edge of the substrate 2. In general, this requires a relative movement of the laser beam 7 and the substrate 2 in the x-direction and in the y-direction. This movement can be achieved, for example, with an x-y moving platform or a robot arm to hold the substrate 2 or with an optical fibre (not illustrated) guiding the laser beam 7, which is held in a moveable manner.

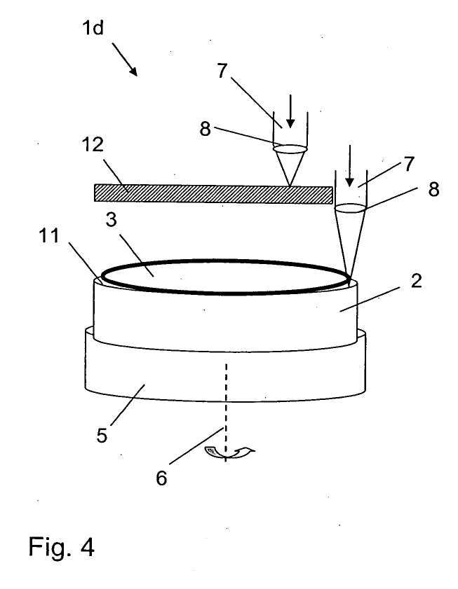

FIG. 4 shows a schematic perspective view of a fourth embodiment of a device 1d according to the present invention. The device 1d comprises an aperture 12, which is not transparent to the laser beam 7 and which therefore prevents the laser beam 7 from being imaged onto regions of the substrate 2 other than the edge region 4 which is to be removed. The aperture 12 is expediently arranged at a slight distance from the surface of the substrate. Accordingly, diffraction effects can occur close to the edge of the screen 12, thereby providing an additional degree of freedom for specifying and removing an appropriate volume of the edge region 4.

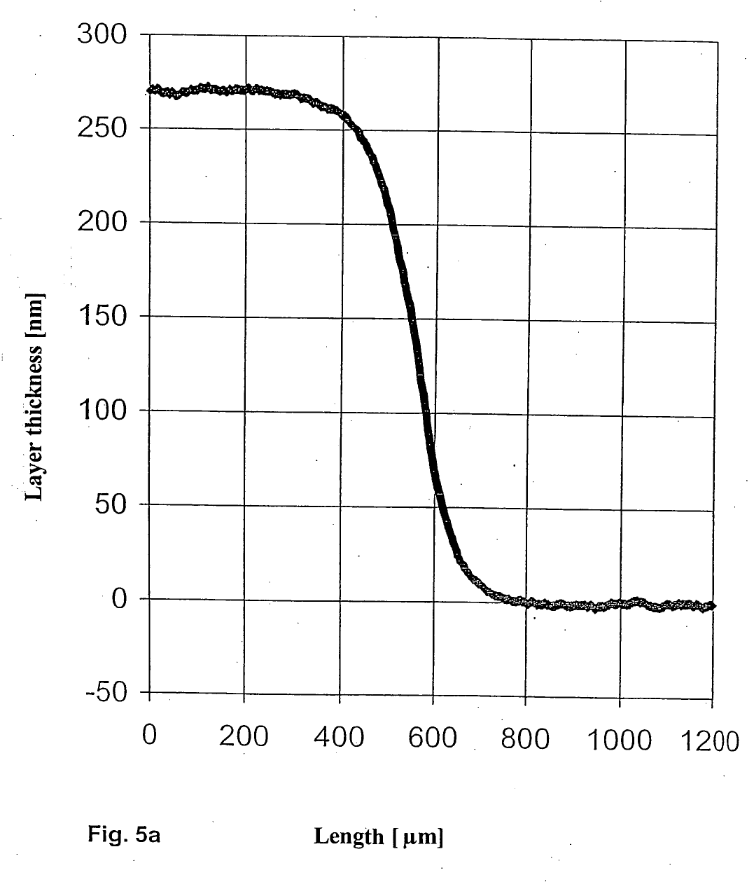

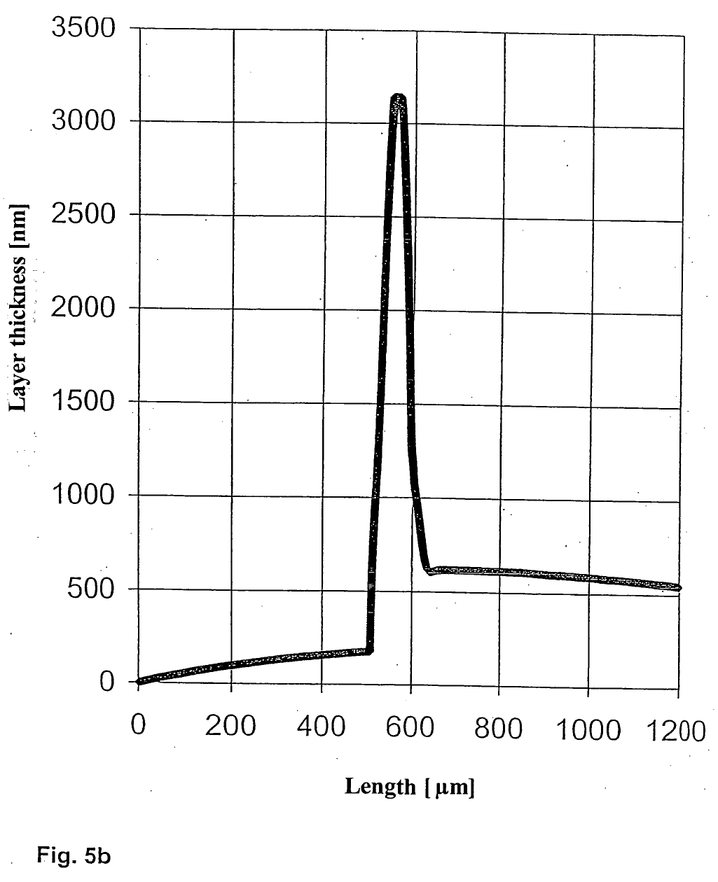

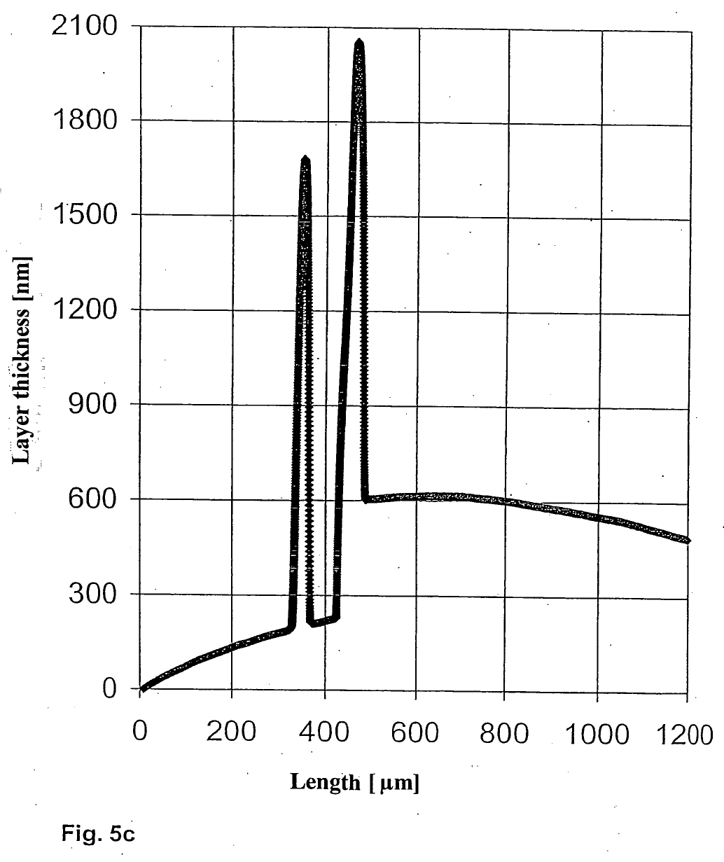

FIG. 5a shows the results of a mechanical profile measurement of an edge region of a mask blank, which has been removed according to the present invention. A mask blank made from quartz glass was coated with an insoluble and/or hardly soluble electron-beam resist (type ZEP 7000, manufactured by Nippon Zeon) and hardened at a temperature (baking temperature) of 200° C. Following this, the electron-beam resist was removed using a laser beam as described above. The edge region was then measured with a profile meter (type: Dektat). In FIG. 5a, the measured layer thickness in nm is plotted against the direction perpendicular to the edge region as a length in micrometers. As shown in FIG. 5a, the layer thickness in the edge region falls from approximately 270 nm to zero over a length of 200 micrometers. The edge of the applied resist layer declines continuously, without any thickening of the layer in this region. Overall, the layer thickness therefore declines evenly and essentially without cracks and/or unevenness of the edge outline. The front face of the removed edge region is essentially free from the resist layer applied, so that a layer disposed beneath it can also be contacted from the side, for example, in order to divert electrical charges.

FIGS. 5b and 5c show, by way of comparison, the results of mechanical profile measurements of an edge region of a mask blank, which has been removed in the conventional manner by a spraying a solvent onto the edge region. A mask blank made from quartz glass was coated with a soluble photo resist (type IP3600). Because a photo resist was used in these exemplary embodiments, the photo-resist paint layer used is thicker by comparison with FIG. 5a. Following this, the applied photo resist was removed by spraying a solvent capable of dissolving the photo resist onto the edge region. As in the case of the first exemplary embodiment, the edge region was then measured using a profile meter (type: Dektat). In FIGS. 5b and 5c, the measured layer thickness in nm is plotted against the direction perpendicular to the edge region as a length in micrometers.

As can be seen from FIG. 5b, the layer thickness in the edge region declines more strongly from approximately 500 nm over a length of approximately 150 micrometers, then falls to zero over a length of approximately 400 micrometers. However, the edge of the applied resist layer does not decline continuously. On the contrary, in the edge region, there is initially a considerable thickening of the layer, the layer thickness increasing to more than 3000 nm. Overall, the layer thickness does not therefore decline evenly, but the edge contour provides a maximum, the height of which significantly exceeds the thickness of the resist layer applied.

In the case of the exemplary embodiment shown in FIG. 5b, the nozzle for selective spraying of the solvent was moved only once, while in the case of the exemplary embodiment shown in FIG. 5c, the nozzle for selective spraying of the solvent was moved twice. As can be seen from FIG. 5c, the layer thickness in the edge region declines more strongly from approximately 500 nm over a length of approximately 200 micrometers, then falls to zero over a further region of approximately 300 micrometers. However, the edge of the applied resist layer does not decline continuously. On the contrary, within the edge region, there are initially two regions with a considerable layer thickening, the layer thickness rising to more than 2000 nm and 1600 nm respectively. Overall, the layer thickness does not decline evenly, but the edge contour provides two maxima, the heights of which significantly exceed the thickness of the resist layer applied.

In the case of the exemplary embodiments according to FIGS. 5b and 5c, the front face of the removed edge region is not completely free from the applied resist layer. On the contrary, the thickness of the resist layer declines in two regions, initially strongly—apart from the layer thickening observed—and, following this, gradually. Accordingly, a layer disposed beneath the paint layer either cannot be contacted from the side, for example, in order to divert electric charges, or can only be contacted from the side subject to limitations.

As shown in the figures, the substrate 2 may provide an exterior contour of any shape required. However, circular or rectangular exterior contours are preferred. The substrate may be a semiconductor substrate, for example, a wafer, glass or quartz-glass plate, for example, a substrate for an LCD display or a mask blank may be used, or any other substrate for use in the lithographic manufacture of micro-electronic components, for example, a mask onto which a photoresist layer is to be applied, which is subsequently to be removed. The layer to be removed may be a photoresist layer, a protective resist layer, a thin metallic coveting or a thin dielectric layer or a system comprising several thin dielectric layers. The parameters of the laser beam can be adapted in an appropriate manner to the properties of the substrate and the layer to be removed.

Relevant parameters of the laser are, in particular, the laser power, the mean pulse duration of the laser pulses, their repetition rate, the laser wavelength and the diameter of the laser beam in the region of the focus. According to the present invention, a laser power in the region of approximately 50W to approximately 100W is preferred. The laser power may be up to 200W, the limit being provided essentially only by the destruction threshold of the substrate 2 disposed beneath the layer 3 which is to be removed. In addition to the removal process, the thermal power absorbed by the substrate 2 and the associated mechanical stresses also contribute to the destruction threshold of the substrate 2.

CO2-lasers, Nd:YAG lasers, frequency-doubled or frequency-tripled Nd:YAG lasers, Excimer lasers, semiconductor-diode lasers or diode-pumped solid state lasers may, for example, be considered as the laser light source. The wavelength of the laser is adapted to the properties of the material to be removed and may, for example, be set to an absorption band or rotational band of the material to be removed or close to such a band.

The velocity of travel at which the laser beam and substrate move relative to one another provides a further parameter, which can determine the quality of removal of the edge region.

According to the present invention, the relevant parameters can be specified on the basis of values based on experience, for example, in tables, or can be monitored and adapted and/or controlled continuously during the removal process. According to the latter alternative, a removed edge region or a removed test field, which is coated in an essentially identical manner to the edge region to be removed, can be optically detected and evaluated. One example for a test field 13 presented in FIG. 3 is disposed in the immediate proximity to the edge region 4 to be removed.

Of course, the test field 13 may also be disposed at any other position also away from or exterior of the substrate 2. If the quality of removal is to be evaluated of the basis of the edge region 4, then the edge region in the immediate proximity of the laser focus 10 can be used, or an edge region disposed downstream of the laser focus 10 in the direction of travel, which has already been removed, may also be used.

The test field and/or the already removed edge region can be optically scanned and evaluated in reflection, transmission or on the basis of scattered light. In principle, to evaluate the quality of the removal, a removed edge region or a removed test field can, in principle, also be evaluated microscopically or using a macroscopic image.

The evaluation is preferably carried out using a computer, wherein the detected values and/or images are evaluated and compared with previously stored reference values. In the event of an undesirable deviation, one or more of the previously-named, relevant parameters can be adapted or controlled until an adequate quality of removal is determined in the edge region and/or test field.

Using the above method, the edge region can be removed to any extent required, for example, up to half thickness or any other thickness of the layer 3 to be removed. However, by preference, the layer of the edge region 4 is essentially completely removed. With an appropriate choice of the relevant parameters, the edge region may also be appropriately structured or patterned, for example, smoothed or rounded. The method according to the invention is characterised by a particularly gentle removal of the edge region 4, without the deposition of disturbing fragments or particles on other regions of the layer 3 which are not be removed.

Although the method according to the invention described above operates without any additional use of solvents and/or etching media, the method may in principle also use appropriate solvents and/or etching media, for example, in subsequent processing stages. Indeed, in view of the particularly gentle removal provided with the method according to the invention, subsequent processing stages of this kind result in less errors or inhomogeneities in the layer applied to the substrate.

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosureof all applications, patents and publications, cited herein and of corresponding German application No. 103 18 681.6, filed Apr. 24, 2003 is incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

1. A method for removing an edge region of a layer applied to a substrate for use in a microlithographic process, in which method, a laser beam is imaged onto the edge region, wherein the laser beam removes the edge region by evaporation.

2. The method according to claim 1, wherein the laser beam is focused in the form of a point or a line onto the edge region by means of an imaging means.

3. The method according to claim 1, wherein the laser beam is imaged onto the edge region in such a manner that the laser beam is incident on the surface of the substrate in an essentially perpendicular direction.

4. The method according to claim 1, wherein the laser beam is imaged onto the edge region in such a manner that the laser beam is incident on a plane spanned by the substrate surface in an essentially parallel direction, wherein the laser beam is incident on an edge of the substrate in a tangential direction.

5. The method according to claim 1, wherein evaporated fragments and particles of the edge region are removed by a vacuum device or a blower device, which is arranged in the proximity of the edge region.

6. The method according to claim 1, wherein the substrate is essentially circular and the layer comprises a coating of a photoresist.

7. The method according to claim 1, wherein the laser beam and the substrate are moved relative to one another, while the laser beam scans the edge region in order to remove the latter.

8. The method according to claim 1, wherein the edge region removed by the laser beam or a test field coated in an essentially identical manner to the edge region, is optically scanned, in order to adapt or regulate a parameter of the laser beam in such a manner that the edge region or the test field is essentially removed in its entirety.

9. The method according to claim 1, wherein an aperture means prevents the laser beam from being imaged onto regions of the substrate other than the edge region, which is to be removed.

10. A method for coating a substrate with a layer, in particular, with a photoresist layer, for use in a microlithographic process, in which method, a layer is applied to the substrate, and an edge region of the applied layer is removed by imaging a laser beam onto the edge region, so that the laser beam removes the edge region by evaporation.

11. An apparatus for removing an edge region of a layer applied to a substrate, for use in a microlithographic process, comprising a laser light source for emitting a laser beam, and imaging means for imaging the laser beam onto the edge region of the substrate, wherein the laser light source is adapted for removing the edge region by means of the laser beam by evaporation.

12. The apparatus according to claim 11, wherein the imaging means is designed to focus the laser beam onto the edge region in the form of a point or line.

13. The apparatus according to claim 11, wherein the imaging means is designed to image the laser beam onto the edge region in such a manner, that the laser beam is incident on the surface of the substrate in an essentially perpendicular direction.

14. The apparatus according to claim 11, wherein the imaging means is designed to image the laser beam onto the edge region in such a manner, that the laser beam is incident on a plane spanned by the surface of the substrate in an essentially parallel direction, wherein the laser beam is incident on an edge of the substrate in a tangential direction.

15. The apparatus according to claim 11, wherein a vacuum device or a blower device is arranged in the proximity of the edge region, in order to remove evaporated fragments and particles of the layer from the edge region by vacuum or blowing.

16. The apparatus according to claim 11, further comprising a holding means for holding a substrate, which is essentially circular and onto which a photoresist layer has been applied by means of spin coating.

17. The apparatus according to claim 11, which is configured in such a manner that the laser beam and the substrate are moved relative to one another, while the laser beam scans the edge region in order to remove the latter.

18. The apparatus according to claim 11, further comprising an optical scanning device for scanning optically either the edge region removed by the laser beam or a test field, which is coated in a manner essentially identical to the edge region, in order, in this manner, to adapt or regulate a parameter of the laser beam, in such a manner that the edge region or the test field is removed essentially in its entirety.

19. The apparatus according to claim 11, further comprising an aperture means to prevent the laser beam from being imaged onto regions of the substrate other than the edge region, which is to be removed.

20. An apparatus for coating a substrate with a layer for use in a microlithographic process, comprising:
a coating device for applying the layer to the substrate;
a laser light source for emitting a laser beam; and
an imaging means for imaging the laser beam onto the edge region of the substrate, wherein the laser light source is adapted for removing of the edge region with the laser beam by evaporation.

21. A substrate, which is coated with a layer for use in a microlithographic process, wherein an edge region of the layer is removed by imaging a laser beam onto the edge region for removing the edge region by evaporation.

22. The substrate according to claim 21, wherein the layer comprises a hardly soluble photoresist.

23. The substrate according to claim 22, wherein the edge region is removed essentially evenly, a front face of the edge region being essentially free from the layer to be removed.
